(19) United States
(12) Patent Application Publication
(10) Pub. No.: US 2020/0204455 A1
(43) Pub. Date: Jun. 25, 2020

(54) Complex Software System Modeling

(71) Applicant: Stackray Corporation, Mill Valley, CA (US)

(72) Inventor: David Bergman, New York, NY (US)

(21) Appl. No.: 16/543,871

(22) Filed: Aug. 19, 2019

Related U.S. Application Data
(63) Continuation of application No. PCT/US18/19194, filed on Feb. 22, 2018.
Application No. PCT/US18/19194 is a continuation of application No. 15/365,257, filed on Nov. 30, 2016, now abandoned.
(60) Provisional application No. 62/462,149, filed on Feb. 22, 2017.

(51) Int. Cl. H04L 12/24; G05B 17/00; G06F 11/30; G06F 30/20

(52) U.S. Cl. CPC H04L 41/145; G05B 17/00; H04L 41/046; G06F 11/3006; G06F 30/20; G06F 11/3051

(57) ABSTRACT

Disclosed is a computer-based method for automatically detecting characteristics of a complex software system. This system can be implemented with networked physical devices such as workstations, using portable devices and smaller IoT devices, and on devices that are virtualized. The method includes receiving machine-readable information about the computers, including information services and software, and building and storing a machine-readable model based on the received information. The model can be a stratified machine-readable model of the software, services, and further computer aspects. The method can also include updating the model and responding to user commands to access both stored and updated models, and/or displaying tagged and/or filtered visual representations of the model to the user. A learning method can be applied to the network using the machine-readable model, with the applying accessing artificial intelligence tags for the model, and associating artificial intelligence tags to elements of the model based on the application of the learning model to the network.

### CROSS-REFERENCE TO RELATED APPLICATION

This application is a continuation of PCT application no. PCT/US18/19194, filed Feb. 22, 2018, which claims priority to provisional application No. 62/462,149, filed Feb. 22, 2017, and is a continuation of U.S. application Ser. No. 15/365,257, filed Nov. 30, 2016, which claims priority to PCT application no. PCT/US2016/047920, filed Aug. 19, 2016, and which claims priority to provisional application no. 62/207,369, filed Aug. 19, 2015. All of these applications are herein incorporated by reference.

### FIELD OF THE INVENTION

This invention relates to methods and apparatus for analyzing computer networks, such as by building and analyzing models of such networks.

### BACKGROUND OF THE INVENTION

Networked computer systems consisting of networked computers that generally each run an operating system and a variety of other software applications are now ubiquitous and are notably found in corporate and government organizations. These generally include computers, such as workstations and servers, that are interconnected via a communication network, such as via an internet protocol (IP) network. Each computer can run a variety of different programs and these programs can communicate with each other via the network. But as these systems increase in size and scope, often spanning tens or hundreds of server instances and thousands of processes, it becomes more and more difficult to fully understand them.

### SUMMARY OF THE INVENTION

In one general aspect, the invention features a computer-based method for automatically detecting characteristics of a computer system that includes a plurality of different running computers connected by a digital communication network. The method includes receiving machine-readable information about the computers in the computer system, including machine-readable information about the services and software for the computers in the computer system, and building and storing a machine-readable model of the software and services in the computer network based on the received information. It also includes updating the model, storing the updated model, and responding to user commands to access both the stored model and the stored updated model.

In preferred embodiments, the steps of storing a model and storing an updated model can store both the models in a single meta-model. The step of responding to the user commands can respond to a difference command to show differences between the stored model and the updated model. The step of storing an updated model can include storing change tags for parts of the model that have changed between the stored model and the updated stored model. The method can further include displaying a filtered visual representation of the model to the user. The method can further include the step of receiving further machine-readable information about the computers in the computer system reflecting changes in the computer system, with the step of updating the model updating the model to reflect the changes in the computer system. The step of updating can include storing a projection map. The step of updating can include storing a difference map. The step of updating can include storing a zoom map.

In another general aspect, the invention features a computer-based system for automatically detecting characteristics of a computer system that includes a plurality of different running servers connected by a digital communication network. This apparatus includes stored instructions operative to receive machine-readable information about the computers in the computer system, including machine-readable information about the services and software for the computers in the computer system, and stored instructions operative to build and store a machine-readable model of the software and services in the computer network based on the received information. The apparatus also includes stored instructions operative to update the model, stored instructions operative to store the updated model, and stored instructions operative to respond to user commands to access both the stored model and the stored updated model.

In a further general aspect, the invention features a computer-based system for automatically detecting characteristics of a computer system that includes a plurality of different running servers connected by a digital communication network. This apparatus includes means for receiving machine-readable information about the computers in the computer system, including machine-readable information about the services and software for the computers in the computer system, means for building and storing a machine-readable model of the software and services in the computer network based on the received information, means for updating the model, means for storing the updated model, and means for responding to user commands to access both the stored model and the stored updated model.

In another general aspect, the invention features a computer-based method for automatically detecting characteristics of a computer system that includes a plurality of different running computers connected by a digital communication network, including receiving machine-readable information about the computers in the computer system, including machine-readable information about the services and software for the computers in the computer system, and building and storing a machine-readable model of the software and services in the computer network based on the received information. The method also includes adding tags to elements of the model, and displaying a tagged visual representation of the model to a user.

In preferred embodiments, the tags can include user-defined tags. The step of displaying the representation of the model can present visual attributes for elements of the model to the user that are selected based on tags associated with those elements. The step of displaying the representation of the model can present elements of the model to the user in colors that are selected based on tags associated with those elements. The step of displaying the representation of the model can present elements of the model to the user in shapes that are selected based on tags associated with those elements. The step of displaying the representation of the model can present elements of the model with alphanumerical annotations that identify tags associated with those elements. The method can further include the step of receiving updates for at least some of the tags and displaying an updated tagged representation of the model to the user. The method can further include the step of receiving real-time updates for at least some of the elements of the models and displaying an updated tagged representation of the model to the user. The tags can include system-defined tags assigned to the elements using heuristics.

In a further general aspect, the invention features a computer-based system for automatically detecting characteristics of a computer system that includes a plurality of different running servers connected by a digital communication network. This apparatus includes stored instructions operative to receive machine-readable information about the computers in the computer system, including machine-readable information about the services and software for the computers in the computer system, and stored instructions operative to build and store a machine-readable model of the software and services in the computer network based on the received information. The apparatus also includes stored instructions operative to add tags to elements of the model, and stored instructions operative to display a tagged visual representation of the model to a user.

In another general aspect, the invention features a computer-based system for automatically detecting characteristics of a computer system that includes a plurality of different running servers connected by a digital communication network. This apparatus includes means for receiving machine-readable information about the computers in the computer system, including machine-readable information about the services and software for the computers in the computer system, means for building and storing a machine-readable model of the software and services in the computer network based on the received information, means for adding tags to elements of the model, and means for displaying a tagged visual representation of the model to a user.

In a further general aspect, the invention features a computer-based method for automatically detecting characteristics of a computer system that includes a plurality of different running computers connected by a digital communication network, which includes receiving machine-readable information about the computers in the computer system, including machine-readable information about the services and software for the computers in the computer system, building and storing a machine-readable model of the software and services in the computer network based on the received information. The method also includes receiving a filter function for the model from a user, applying the filter function to the model, and displaying a filtered version of the model to the user.

In preferred embodiments, the step of receiving a filter function can receive a tri-level Boolean filter function that allows portions of the model to be included, excluded, or have their inclusion unaffected. The step of receiving a filter function can include receiving a tag-based filter function. The step of receiving a filter function can include receiving a graph-specific filter function. The step of receiving a filter function can include receiving a filter function that specifies a focal point within the model. The step of receiving a filter function can include receiving a filter function that specifies a path distance within the model. The step of displaying can display an interactive filtered version of the model, with the method further including the step of updating the displayed model in response to user interaction with the displayed model. The step of displaying the model can display a three-dimensional representation of the model.

In another general aspect, the invention features a computer-based system for automatically detecting characteristics of a computer system that includes a plurality of different running servers connected by a digital communication network. This apparatus includes stored instructions operative to receive machine-readable information about the computers in the computer system, including machine-readable information about the services and software for the computers in the computer system, and stored instructions operative to build and store a machine-readable model of the software and services in the computer network based on the received information. The apparatus also includes stored instructions operative to receive a filter function for the model from a user, stored instructions operative to apply the filter function to the model, and stored instructions operative to display a filtered version of the model to the user.

In a further general aspect, the invention features a computer-based system for automatically detecting characteristics of a computer system that includes a plurality of different running servers connected by a digital communication network. This apparatus includes means for receiving machine-readable information about the computers in the computer system, including machine-readable information about the services and software for the computers in the computer system, means for building and storing a machine-readable model of the software and services in the computer network based on the received information, means for receiving a filter function for the model from a user, means for applying the filter function to the model, and means for displaying a filtered version of the model to the user.

In another general aspect, the invention features a computer-based method for automatically detecting characteristics of a computer system that includes a plurality of different running computers connected by a digital communication network, including receiving machine-readable information about the computers in the computer system, including machine-readable information about the services and software for the computers in the computer system. The method also includes receiving machine-readable information about further aspects of the computers, building and storing a stratified machine-readable model of the software, services, and further computer aspects in the computer network based on the received information.

In preferred embodiments, the step of receiving machine-readable information about further aspects of the computers can include receiving real-time information about the computers. The step of building a stratified model can include building a model with a metrics layer. The method can further include the steps of receiving and displaying real-time updates for at least some elements of at least one layer of the stratified model. The step of building a stratified model can include building a model with an events layer. The step of building a stratified model can include building a model with an alerts layer. The step of building a stratified model can include building a model with a calculation layer.

In a further general aspect, the invention features a computer-based system for automatically detecting characteristics of a computer system that includes a plurality of different running servers connected by a digital communication network. This apparatus includes stored instructions operative to receive machine-readable information about the computers in the computer system, including machine-readable information about the services and software for the computers in the computer system, and stored instructions operative to build and store a machine-readable model of the software and services in the computer network based on the received information. The apparatus also includes stored instructions operative to receive machine-readable information about further aspects of the computers, and stored instructions operative to build and store a stratified machine-readable model of the software, services, and further computer aspects in the computer network based on the received information.

In another general aspect, the invention features a computer-based system for automatically detecting characteristics of a computer system that includes a plurality of different running servers connected by a digital communication network. This apparatus includes means for receiving machine-readable information about the computers in the computer system, including machine-readable information about the services and software for the computers in the computer system, means for building and storing a machine-readable model of the software and services in the computer network based on the received information, means for receiving machine-readable information about further aspects of the computers, and means for building and storing a stratified machine-readable model of the software, services, and further computer aspects in the computer network based on the received information.

In a further aspect of the invention, the invention features a computer-based method for automatically detecting characteristics of a computer system that includes a plurality of different running computers connected by a digital communication network, which includes receiving machine-readable information about the computers in the computer system, including machine-readable information about the services and software for the computers in the computer system, building and storing a machine-readable model of the software and services in the computer network based on the received information. The method also includes applying a learning method to the network using the machine-readable model, with the applying accessing artificial intelligence tags for the model, and associating artificial intelligence tags to elements of the model based on the application of the learning model to the network.

In preferred embodiments, the step of building and storing a machine-readable model can build and store the model as a directed acyclic graph, with the steps of adding and applying being performed for the directed acyclic graphic. The step of applying a learning method can apply the method to real-time metric and topology changes.

In another general aspect, the invention features a computer-based system for automatically detecting characteristics of a computer system that includes a plurality of different running servers connected by a digital communication network. This apparatus includes stored instructions operative to receive machine-readable information about the computers in the computer system, including machine-readable information about the services and software for the computers in the computer system, and stored instructions operative to build and store a machine-readable model of the software and services in the computer network based on the received information. The apparatus also includes stored instructions operative to apply a learning method to the network using the machine-readable model, with the applying accessing artificial intelligence tags, and stored instructions operative to associate artificial intelligence tags to elements of the model based on the application of the learning model to the network.

In a further general aspect, the invention features a computer-based system for automatically detecting characteristics of a computer system that includes a plurality of different running servers connected by a digital communication network. This apparatus includes means for receiving machine-readable information about the computers in the computer system, including machine-readable information about the services and software for the computers in the computer system, means for building and storing a machine-readable model of the software and services in the computer network based on the received information, means for applying a learning method to the network using the machine-readable model, wherein the means for applying accesses artificial intelligence tags, and means for associating artificial intelligence tags to elements of the model based on the application of the learning model to the network.

### BRIEF DESCRIPTION OF THE DRAWING

FIG. 1 is a block diagram of an illustrative model building and analysis system according to the invention;

FIG. 2 is a screenshot of a network analysis screen from a network analysis workstation for the system of FIG. 1;

FIG. 3 is a screenshot of a model exploration sidebar for the network analysis screen of FIG. 2;

FIG. 4 is a screenshot of a property viewing sidebar for the network analysis screen of FIG. 2;

FIG. 5 is a screenshot of a tag selection dialog for the network analysis screen of FIG. 2;

FIG. 6 is a screenshot of the model exploration sidebar of FIG. 3 showing tri-level Boolean filtering controls,

FIG. 7 is a screenshot of the model exploration sidebar of FIG. 3 with its visualization tool expanded to show visualization controls, and

FIG. 8 is a screenshot of the network analysis screen of FIG. 2, showing a meta-map view.

### DETAILED DESCRIPTION OF AN ILLUSTRATIVE EMBODIMENT

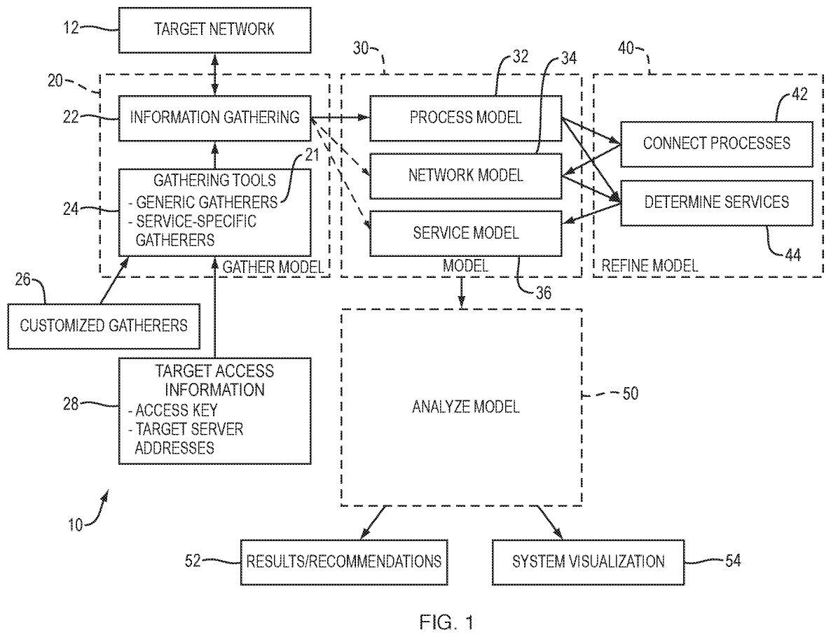

Referring to FIG. 1, a model building and analysis system 10 usable in connection with the invention includes an information gathering subsystem 20 that can be connected to a running target network 12 that includes a plurality of computers, which can include physical devices such as workstations, portable devices and smaller IoT devices, devices that are virtualized such as through VMWare or Docker, and routers. The information gathering subsystem includes an information gathering controller 22 that is responsible for deploying information gatherers of different types on the various computers on the target network, and uses returned information to build a stratified model of the particular target system in model storage 30 based on a meta model that will be described in more detail below. A model refinement subsystem 40 is also provided to refine the model. And a model analysis subsystem 50 is provided to analyze the model and thereby derive analysis results, such as system visualizations 54 as well as listings of results, and/or recommendations for modifications of the system 52.

The model storage 30 can be implemented using a database and is divided into three parts. These store three parts of the model, including the process model layer 32, the connection model layer 34, and the service model layer 36. The model refinement subsystem 40 includes a process connector 42 and a service analyzer 44 that can each refine the model. The implementation and operation of this type of system is described in more detail in the above-referenced applications, which are herein incorporated by reference.

The operation of the model analysis subsystem 50 in producing interactive system visualizations 54 will now be discussed in more detail. In this embodiment, the analysis system presents interactive visualizations to the user on a workstation such as a personal computer, tablet, or smartphone. This can allow the user to explore and interact with the model of the target network in a variety of ways, such as through filtering and tagging, and by creating and comparing snapshots from the model.

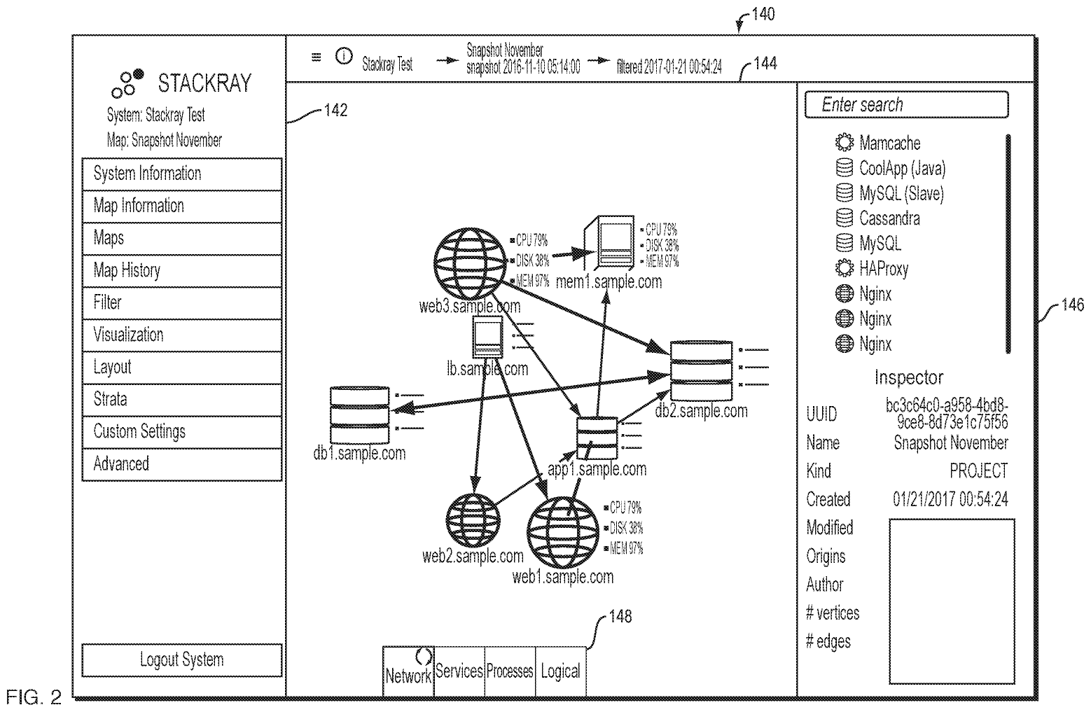

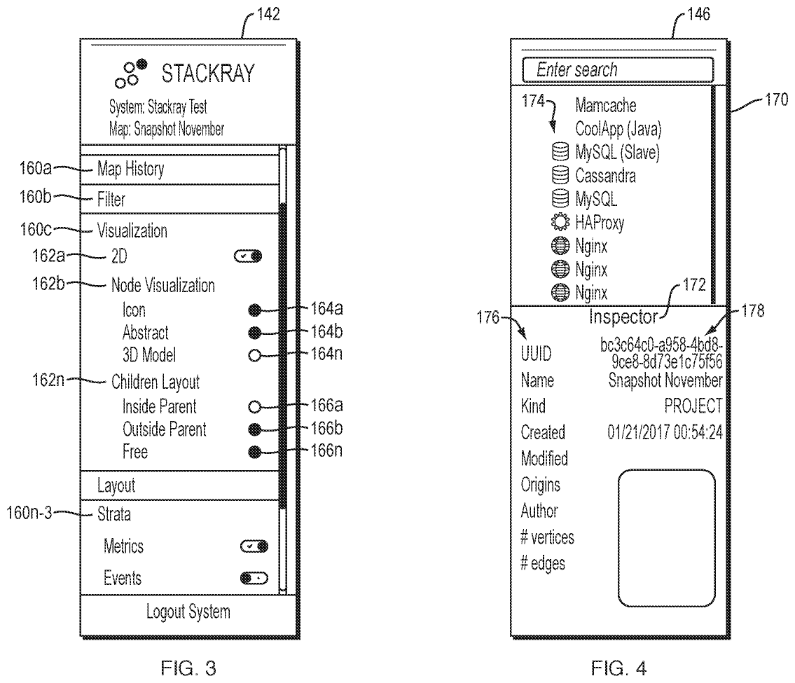

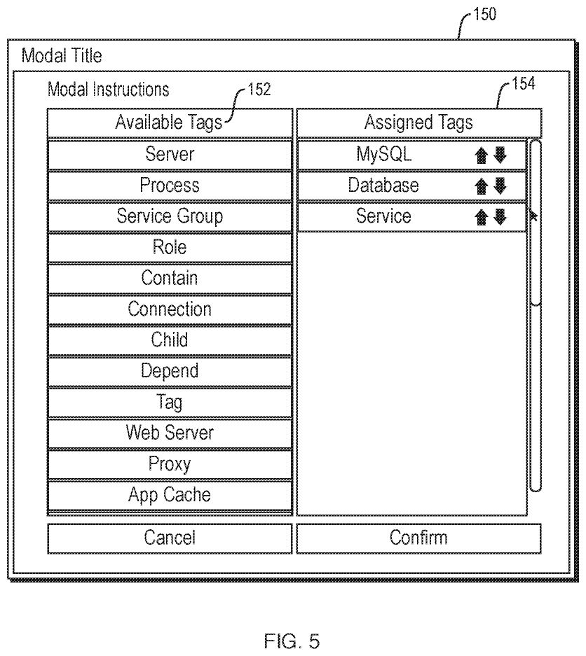

Referring also to FIG. 2-4, an illustrative workstation presents the user with an interactive network analysis screen 140 that includes an interaction tool suite. This suite can include a model exploration sidebar 142, a model representation window 144, and a property viewing sidebar 146. The user uses tools in the model exploration sidebar to customize the view of the parts of the model that he or she is interested in, and views properties of elements of the model in the property exploration sidebar.

The model exploration sidebar 142 can be organized as a set of expanding tool category entries 160a, 160b, . . . 160n. These category entries can be expanded to show one or more levels of sub-entries 162a, 162b, . . . 162n of various types, which can correspond to different kinds of controls 164a, 164b, . . . 164n, 166a, 166b, . . . 166n.

The property viewing sidebar can include a search/selection panel 170 that allows users to search and select parts of the model textually or through the use of type icons 174 for elements currently being displayed. It can also include an inspector panel 172 that shows properties 176 and corresponding values 178 for selected elements in the model. The user can use standard input devices, such as a keyboard, mouse and/or touchscreen, in a variety of ways to select which parts of the model are to be displayed, such as by searching the model, filtering the model, perusing through the model, rotating the model, drag-selecting parts of the model, or drilling into or out of the model.

Once a portion of the model has been selected for display, it can be rendered as an annotated directed graph in two or three dimensions in the model representation window 144. The elements of this graph can be rendered in ways that convey information about them, using any suitable visual cues, such icons, text, or colors. Nodes can be represented by differently shaped icons that represent their role in the network, for example, such as “database,” “server,” “or proxy.” The user can select the attributes to be assigned to rendered model elements using the visualization tool 160c and related controls. One of ordinary skill in the art would of course recognize that there are many other ways to present and organize the user interface elements of the network analysis screen 140.

One way that a user can interact with the model is through tags. Elements of the model at different layers, such as, network nodes, processes, or services, can each be tagged with one or more system- or user-defined tags. In this embodiment, available tags are assigned automatically by heuristics in the model analysis subsystem 50, and users can also assign available tags using a tag selection dialog 150. A “Role” tag can store a node's role, such as “database,” “server,” “or proxy.” Heuristics can include looking for what exact executables are behind processes running, what configuration files are found on computers, or what communication ports are open, and deduce a certain computer service tag or role tag based on such patterns. For instance, detecting that the service MySQL is running based the port 3306 is open on the computer, that the specific MySQL configuration file is found or that a process is running an executable named “mysql”.

The tag values can be presented to the user in the inspector panel 172 and/or in the model representation window 140. They can affect visual attributes presented for an element such as its icon or color, or they can be displayed as text associated with the element. Users can create user-defined tags for any property they choose and associate them with a color or other visual attribute. They can override color or other visual attributes for predefined tags, as well.

The model analysis subsystem 50 can also allow users to apply various forms of filtering to the model to obtain projections, which are filtered versions of the map. This functionality allows the user to focus on or find parts of the model in the model representation window 144. Some ways to filter the model include text-based searching, Boolean searching, tag searching, and graph-specific searching. Graph-specific searching can allow a user to search based on graph topology. Specifying a path length and type parameters, for example, can allow the user to look at nodes that are a defined number of steps away from a focal point in the model using a particular path type (e.g., two steps via TCP/IP). Filtering can be applied using the filter tool 160b.

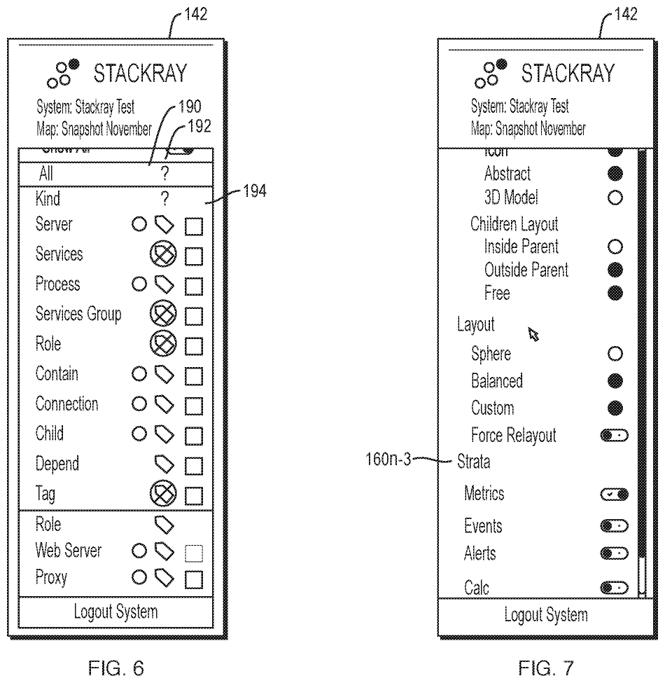

Referring also to FIG. 6, this embodiment also supports a tri-level Boolean search setting with values of include 190, exclude 192, and ignore 194. The exclude value allows nodes having that tag to vanish from the visual representation, while the ignore value will cause the system to act as if nodes were not tagged with that specific tag.

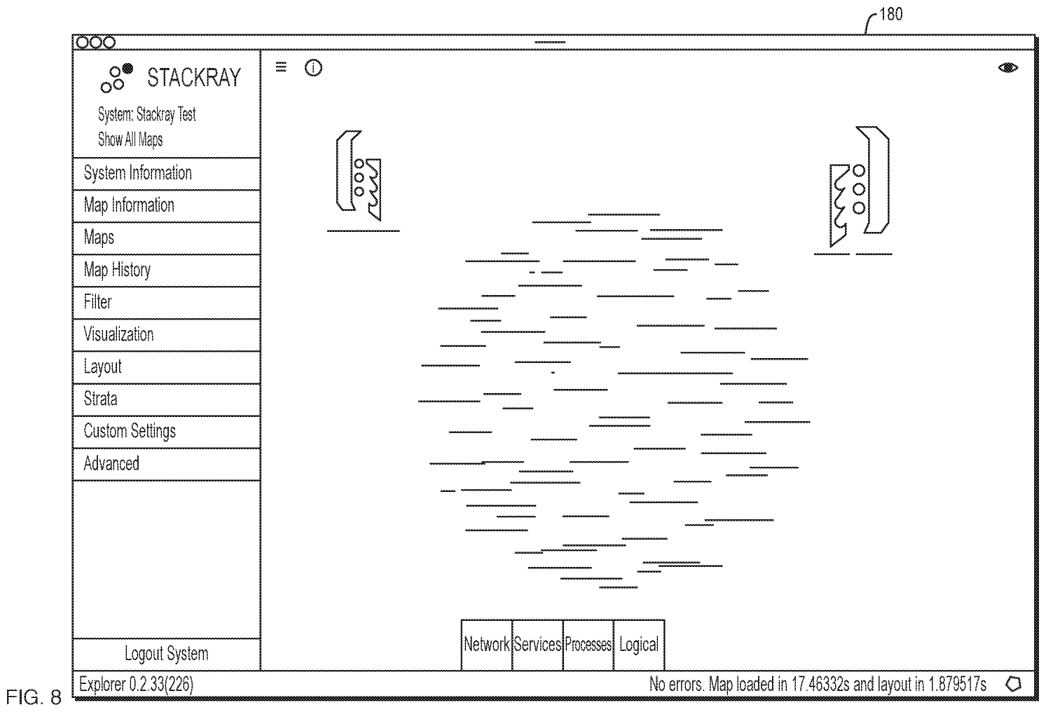

Another way that the user can interact with the model is by accessing snapshots of the model as it is zoomed, filtered or changed to reflect changes in the underlying network. This functionality is supported by storing the model as a meta-graph. In this embodiment, when the network is updated or the model is filtered, a new entry in the meta-graph can be stored, allowing the user to selectively access the model in different previous states. One way to implement this meta-graph functionality is to organize commits to the network graphs in a larger directed acyclic graph, using an approach similar to one used in the well-known Git version control system. Some or all of the meta-map can be displayed in the interactive network analysis screen 140, as shown in FIG. 8.

The user can also perform graph operations on the meta-graph. One such operation is a difference operation, which allows the user to look at how a network has changed. This can be helpful in debugging problems that arise after a network has been reconfigured. Diff maps can be highlighted in the meta-map view, such as with a red flag.

Difference tags can be used to help the user understand network changes. These can include add tags, delete tags, and change tags. These types of tags can also possess inheritance so that a user can see that a subpart of a network has changed. This can help to guide him or her to drill into these parts of the model to understand the specifics of changes to the network. Map history functionality can be accessed through a map history tool 160a.

Another type of map is a zoom map. Zoom maps are filtered aspects of the model which include elements related to a specific element in the model, such as all elements inside a specific computer or a specific computer service.

Referring to FIG. 7, the model can include layers in addition to the process model layer 32, the connection model layer 34, and the service model layer 36. These additional layers can include static and real-time elements. Real-time elements can model a variety of aspects of the network as it operates. They can include elements for metrics, events, alerts, and calculations, and they can be updated either continuously or on request. Values for real-time elements, such as CPU activity percentages, can be displayed as text in or near an element, arcs in an element, or in any other suitable way.

Strata can also be bundled and manipulated together. A stratum selection tool 148 in the interactive network analysis screen 140 can allow the user to select data from some or all of the strata. A real-time stratum tool 160n-3 can also provide controls that allow real-time layers to be shown or hidden.

The model can also include an Artificial Intelligence (AI) stratum. This stratum can store values, such as weights, that can be used in iteratively training various kinds of learning methodologies. These can then be used to detect potential areas of concern in the network.

In overall operation, the various tools can cooperate to allow users to quickly and interactively understand their networks. They can look into how a problem arose during network modification, for example, by performing difference operations on the network, and they can then use searching, filtering, and direct interactions, such as drill-down operations to investigate the parts of the system that were affected.

The system described above can operate using special-purpose hardware, software running on general-purpose processors, or a combination of both. In the embodiment described above, for example, the model analysis subsystem is designed to allow users to view a interactive network analysis screens on a variety of standard desktop and mobile devices. In addition, while the system can be broken into the series of modules shown in FIG. 1, one of ordinary skill in the art would recognize that it is also possible to combine them and/or split them to achieve a different breakdown. The specific implementation of parts of the system including the model structure and the analysis and visualization tools can also vary depending on a variety of factors, including the objectives for the model and the type of target system being analyzed.

The present invention has now been described in connection with a number of specific embodiments thereof. However, numerous modifications which are contemplated as falling within the scope of the present invention should now be apparent to those skilled in the art. Therefore, it is intended that the scope of the present invention be limited only by the scope of the claims appended hereto. In addition, the order of presentation of the claims should not be construed to limit the scope of any particular term in the claims.

What is claimed is:

1. A computer-based method for automatically detecting characteristics of a computer system that includes a plurality of different running computers connected by a digital communication network, comprising:
receiving machine-readable information about the computers in the computer system, including machine-readable information about the services and software for the computers in the computer system,
building and storing a machine-readable model of the software and services in the computer network based on the received information,
updating the model,
storing the updated model, and
responding to user commands to access both the stored model and the stored updated model.

2. The method of claim 1 wherein the steps of storing a model and storing an updated model store both the models in a single meta-model.

3. The method of claim 1 wherein the step of responding to the user commands responds to a difference command to show differences between the stored model and the updated model.

4. The method of claim 1 wherein the step of storing an updated model includes storing change tags for parts of the model that have changed between the stored model and the updated stored model.

5. The method of claim 1 further including displaying a filtered visual representation of the model to the user.

6. The method of claim 1 further including the step of receiving further machine-readable information about the computers in the computer system reflecting changes in the computer system, and wherein the step of updating the model updates the model to reflect the changes in the computer system.

7. The method of claim 1 wherein the step of updating includes storing a projection map.

8. The method of claim 1 wherein the step of updating includes storing a difference map.

9. The method of claim 1 wherein the step of updating includes storing a zoom map.

10. A computer-based system for automatically detecting characteristics of a computer system that includes a plurality of different running servers connected by a digital communication network, comprising:
stored instructions operative to receive machine-readable information about the computers in the computer system, including machine-readable information about the services and software for the computers in the computer system,
stored instructions operative to build and store a machine-readable model of the software and services in the computer network based on the received information,
stored instructions operative to update the model,
stored instructions operative to store the updated model, and
stored instructions operative to respond to user commands to access both the stored model and the stored updated model.

11. A computer-based system for automatically detecting characteristics of a computer system that includes a plurality of different running servers connected by a digital communication network, comprising:
means for receiving machine-readable information about the computers in the computer system, including machine-readable information about the services and software for the computers in the computer system,
means for building and storing a machine-readable model of the software and services in the computer network based on the received information,
means for updating the model,
means for storing the updated model, and
means for responding to user commands to access both the stored model and the stored updated model.

12-46. (canceled)
